(19) United States
(12) Patent Application Publication
(10) Pub. No.: US 2011/0120517 A1
(43) Pub. Date: May 26, 2011

(54) Synthesis of High-Efficiency Thermoelectric Materials

(75) Inventor: Qiang Li, Setauket, NY (US)

(73) Assignee: Brookhaven Science Associates, LLC, Upton, NY (US)

(21) Appl. No.: 12/945,677

(22) Filed: Nov. 12, 2010

Related U.S. Application Data
(60) Provisional application No. 61/261,130, filed on Nov. 13, 2009.

(51) Int. Cl. H01L 35/28; H01L 35/12; B22F 1/00; B22F 3/10; B22F 3/12; H01L 35/34

(52) U.S. Cl. 136/203; 136/236.1; 136/240; 136/238; 419/31; 75/228; 136/201

(57) ABSTRACT

A process for the fabrication of high efficiency thermoelectric materials using non-equilibrium synthesis routes is described. In one embodiment a molten alloy comprising a predetermined ratio of elements which will constitute the thermoelectric material is quenched at a cooling rate in excess of, for example, 10⁵ or 10⁶ K/s using a process such as melt spinning. The rapidly solidified particles are then placed into a mold having the desired size and shape. The particles in the mold are simultaneously compressed and sintered at elevated temperatures for a short duration using, for example, hot pressing or spark plasma sintering. The overall process provides improved microstructural control and greatly expands the accessible phase space, permitting the formation of dense, single-phase structures with nanosized grain boundaries and minimal or no impurity segregation. The process is especially advantageous for the formation of n- and p-type filled skutterudites which may be incorporated in thermoelectric devices.

### CROSS-REFERENCE TO RELATED APPLICATIONS

This application claims the benefit of U.S. Provisional Application No. 61/261,130, filed Nov. 13, 2009, which is incorporated herein by reference in its entirety.

### STATEMENT OF GOVERNMENT RIGHTS

This invention was made with Government support under contract number DE-AC02-98CH10886, awarded by the U.S. Department of Energy. The Government has certain rights in the invention.

### BACKGROUND

I. Field of the Invention

This invention relates generally to thermoelectric materials and processes for their preparation. In particular, the present invention relates to the non-equilibrium synthesis of high efficiency thermoelectric materials. The invention also relates to the use of the thus-formed thermoelectric materials in energy conversion devices.

II. Background of the Related Art

The thermoelectric effect involves the direct conversion of a temperature difference to a voltage or, alternatively, the conversion of an applied voltage (by way of the induced current flow) to a thermal gradient. The former process is known as the Seebeck effect whereas the latter is termed the Peltier effect. A material which is capable of converting heat energy into electrical energy and vice versa is generally known as a thermoelectric material. The figure of merit (ZT) for a thermoelectric material is a dimensionless quantity defined by the expression

$$ZT = \frac{{S}^{2} σ T}{κ}$$

where S is the Seebeck coefficient, σ is the electrical conductivity, κ is the thermal conductivity, and T is the absolute temperature. The Seebeck coefficient is a property intrinsic to the material and is related to the voltage developed in response to a temperature gradient (ΔV/ΔT). When measuring the properties of a thermoelectric material, the Seebeck coefficient is generally provided in units of microVolts per Kelvin (μV/K) whereas the electrical conductivity is in microOhms-meter (μQ·m) and the thermal conductivity is in Watts per Kelvin-meter (W/K·m).

The direct relationship between ZT and σ inverse relationship with κ indicates that the best thermoelectric materials are those that transport electricity efficiently while transporting heat inefficiently. However, the electrical and thermal conductivity of a material are typically interrelated. Materials which are good electrical conductors are generally also good thermal conductors. In the “CRC Handbook of Thermoelectrics”, ed. by D. M. Rowe, Boca Raton, Fla.: CRC Press (1995) on pages 407-440, G. A. Slack proposed that in order to increase the figure of merit ZT it is necessary to develop materials in which phonons experience a high degree of scattering while charge carriers experience minimal scattering during transport. This means that the structure of the material should have the thermal properties of an amorphous material (e.g., a glass), but the electrical properties of a single crystal so that the thermal conductivity is lowered by phonon scattering whereas the lack of electron or hole scattering yields a high electrical conductivity. A material which exhibits this type of behavior has been referred to as phonon-glass electron-single-crystal (PGEC). A review of the PGEC approach to the development of thermoelectric materials has been provided by G. S. Nolas, et al. in “A Phonon-Glass-Electron Crystal Approach to Advanced Thermoelectric Energy Conversion Applications,” Annu. Rev. Mater. Sci. 29, 89 (1999) which is incorporated by reference as if fully set forth in this specification.

There is an interest in developing thermoelectric materials with a still higher value for the figure of merit ZT due to the potential for use with, for example, applications which require solid state cooling or power generation. Potential applications for thermoelectric devices include as a refrigerant for charge couple devices (CCDs), infrared detectors, or computer chips. Thermoelectric materials have also been used to reversibly heat/cool picnic coolers and are being considered for use in the recovery of waste heat from automobile engine exhaust and radiator cooling systems by converting it to electrical power. A number of materials have been investigated for use in thermoelectric devices over a variety of temperature ranges. Some examples include bismuth chalcogenides (e.g., Bi₂Te₃ or Bi₂Se₃), skutterudites (e.g., materials of the form (Co, Ni, Fe)(P, Sb, As)₃, mesoporous materials (e.g., Ru/TiOₓ), thin film/quantum well/quantum wire/quantum dot structures (e.g., PbTe/PbSeTe quantum dot superlattices), intercalation compounds (e.g., Bi/C), heavy fermion/hybridization gap systems (e.g., CeF₄Sb₂), intermetallic semiconductors (e.g., TiNiSn), doped polymeric materials, functionally graded materials, quasicrystals (e.g., Al_{70.8}Pd_{20.9}Mn_{8.3}), doped silicides (e.g. Mg₂Si), and oxides (e.g. Ca₃Co₄O₉). From among these, skutterudites have been shown to be some of the more promising thermoelectric materials due primarily to the nature of their crystal structure.

The basic structure of a binary skutterudite is provided as MX₃ where M represents a metal atom and X a pnictide atom (e.g., from column V of the periodic table). Examples of known semiconductor binary skutterudites include CoP₃, CoAs₃, CoSb₃, RhP₃, RhAs₃, RhSb₃, IrP₃, IrAs₃, and IrSb₃. Skutterudites typically have a large unit cell with an open or cage-like crystal structure. Constituent atoms generally have low coordination numbers and form covalent bonds with their neighbors. This facilitates insertion of smaller atoms into the relatively large interstitial voids present in these materials. Since individual interstitial atoms are free to move about within their comparatively large cages, they may “rattle” and thus interact with lattice phonons. This enables a reduction of the thermal conductivity of the lattice through phonon scattering without significantly reducing the electrical conductivity. Skutterudites which have voids in the crystal structure filled with interstitial atoms are known as filled skutterudites. The specific configuration of filled skutterudites, including the type, size, and location of the interstitial atom, directly influences many of its physical properties.

A number of filled skutterudites have been formed by using filler atoms of lanthanide, actinide, and alkaline-earth elements. Some examples of filled skutterudites are disclosed in U.S. Pat. No. 6,369,314 to George S. Nolas which is incorporated by reference as if fully set forth in this specification. It has been observed that smaller interstitial atoms generally produce a larger degree of phonon scattering due to a greater propensity for “rattling” within the comparatively larger void in the skutterudite crystal structure. In general, filling of voids in the skutterudite structure with interstitial atoms influences the overall structural and electronic stability of the alloy since the interstitial atom may introduce a net positive or net negative charge. In some cases this necessitates the substitution of a constituent atom with another of differing valency in order to maintain charge neutrality. For example, iron (Fe) has been used to replace a number of cobalt (Co) sites in cesium (Ce)-filled skutterudites to produce CeFe₄₋ₓCoₓSb₁₂ compounds. It is also possible to produce filled skutterudites without replacing a metal atom. Some examples in which a binary skutterudite has been fractionally filled by an interstitial atom include La_{0.2}Co₄P₁₂, Ce_{0.25}Co₄P₁₂, Ce_{0.1}Co₄Sb₁₂, and La_{0.23}Co₄Sb₁₂. Doping with an electropositive or electronegative element has also been used to produce n-type and p-type skutterudites for incorporation in solid state electronic devices by adjusting the ratio of substituting atoms and doping atoms. Examples of thermoelectric devices produced from n- and p-type filled skutterudites are provided in U.S. Pat. No. 6,069,312 to Fleurial, et al. which is incorporated by reference as if fully set forth in this specification.

In addition to the phonon-scattering caused by the “rattling” of interstitial atoms in filled skutterudites, there are a number of other mechanisms which affect the thermal conductivity. These include, but are not limited to, scattering arising from point defects, grain boundaries, precipitates, and dislocations within the material. Additional scattering may arise from electronic effects such as charge carriers from dopant atoms and differences in the valency of constituent atoms. The largest reduction in thermal conductivity occurs when most, if not all, of these phonon scattering mechanisms are present in the material. In order to increase the figure of merit ZT, the mechanisms employed to reduce the thermal conductivity should have a minimal effect on the electrical conductivity. An example in which the amount of phonon scattering is increased through microstructure control is provided by U.S. Pat. No. 6,207,886 to Kusakabe, et al. (hereinafter “Kusakabe”) which is incorporated by reference as if fully set forth in this specification. Kusakabe discloses, inter alia, a process for fabricating CoSb₃-based skutterudites that have a higher crystal grain boundary area to grain size ratio (i.e., smaller grains are produced) and include metal oxide particles dispersed at grain boundaries.

Despite the potential of engineering filled skutterudites to produce more efficient thermoelectric materials, their development has been limited by difficulties associated with the control of the phase and microstructure. Conventional materials fabrication techniques used to produce filled skutterudites rely on processes which occur at or near thermodynamic equilibrium. For example, elevated temperature annealing under equilibrium conditions tends to result in phase segregation and grain growth with preferential nucleation of impurity phases occurring at grain boundaries. In this case, rather than being incorporated into voids in the skutterudite crystal structure, filling atoms are present primarily in the segregated phase. This significantly limits any desired increase in performance of the thermoelectric material obtainable through conventional processing techniques.

In view of these and other considerations there is therefore a continuing need to develop novel processing routes which provide further microstructural control during the fabrication of advanced thermoelectric materials. This is especially true for the development of thermoelectric devices since the formation of p- and n-type thermoelectric materials requires precise control over the placement and relative concentrations of their constituent atoms. Furthermore, cost-effective and industrial-scalable technology is particularly important for the development of practical applications which incorporate high performance thermoelectric materials.

### SUMMARY

In view of these and other considerations, there is a need to develop processes f r fabricating thermoelectric materials with still higher energy conversion efficiencies. In particular, there is a need for a method of fabricating thermoelectric materials with a significantly higher figure of merit ZT than what has been realized to date. The present invention provides a cost-effective and industrial-scalable method of fabricating high performance thermoelectric materials using non-equilibrium synthesis routes. The process uses a rapid solidification method comprising initially heating the constituents of the thermoelectric material until a molten liquid mixture is formed. The liquid is cooled to form solid particles using an extremely fast cooling rate which, in one embodiment, is greater than or equal to 10⁵ K/s and, in another embodiment is greater than or equal to 10⁶ K/s. In one embodiment the solid particles are compacted into a mold having the desired shape and are subsequently sintered at an elevated temperature and pressure for a predetermined time period.

In one embodiment the molten liquid mixture is cooled by melt spinning. A thin stream of the liquid is directed onto the circumferential edge of a cooled and rapidly rotating wheel that spins off a thin, solidified ribbon having the desired composition. The wheel typically comprises a metal having a high thermal conductivity such that heat is quickly drawn away from the molten mixture to transform it to the solid phase. The wheel may be cooled through internal channels which permit the flow of a cooling liquid such as water or liquid nitrogen. In one embodiment, the time from when a stream of the molten liquid first begins to cool to the end of the flow is 0.1 to 8 seconds for a sample size of 1 to 100 grams. The solidified ribbon is either amorphous or a partially crystallized solid, and can be crushed or ground into smaller particles for placement in a suitable mold. Grinding may be accomplished by mechanical means or by ball milling prior to sintering. In some embodiments, the molten liquid mixture may be cooled by a thermal spray method or by splash quenching.

The mold is then sintered at elevated temperatures and pressures for a predetermined time period. In one embodiment sintering is accomplished by hot pressing in which the mold is simultaneously compressed and heated to induce sintering of the solid particles. Preferably, hot pressing is performed at a temperature of 350° C. to 750° C. and applied force of 6.3 kN for 2 min. Heating may be performed, for example, using an induction coil, by indirect resistance heating, or by direct resistive heating in which an electrical current is passed directly through the mold. In another embodiment the solid particles may be sintered using spark plasma sintering. This is accomplished by applying a pulsed direct current (DC) through the mold and particle compact. This heats the sample internally through resistive heating and facilitates a very high heating rate of up to 1,000° C./min and, consequently, a shorter sintering time. Spark plasma sintering may be performed at 350° C. to 750° C., or 500° C. to 700° C., at a pressure over an area of about 64 mm² (a circular cross section with a diameter of about 9 mm). In an especially preferred embodiment spark plasma sintering is performed at a temperature of 600° C. and a pressure of 50 MPa for 2 minutes. In yet another preferred embodiment spark plasma sintering is performed at a temperature of 620° C. and pressure of 50 MPa for 2 minutes.

Another embodiment relates to thermoelectric materials formed using the non-equilibrium synthesis procedure described above. The thermoelectric material may, in one embodiment, comprise Re, Fe, Co, and Sb, which together form a Re_{y}Fe₄₋ₓCoₓSb₁₂ compound. In another embodiment the thermoelectric material comprises Ce, Fe, and Sb, which together form a CeFe₄Sb₁₂ compound. In yet another embodiment the thermoelectric material is fabricated from Bi, Se, Sb, and Te in the form of a BiₓSb₂₋ₓTe_{3-y}Se_{y} compound. Still another embodiment relates to a thermoelectric material fabricated from Ce, Fe, Co, and Sb, which together may form a Ce_{0.9}Fe₃CoSb₁₂ compound. The thermoelectric materials so formed are fully dense (at 99%-100% of the theoretical density of the material), with single-phase grains of 2 nm to 1 μm in diameter and virtually no microscopic segregation either within the material or at grain boundaries.

Yet another embodiment of the present invention relates to a thermoelectric device comprising thermoelectric elements formed using the non-equilibrium synthesis routes of the present invention. The thermoelectric device is constructed of a cold plate and a hot plate with a plurality of n-type and p-type thermoelectric elements formed between them. The thermoelectric device may function, for example, as a solid state refrigerant or heater, as an energy conversion device, or as a temperature sensor with improved efficiency.

### BRIEF DESCRIPTION OF THE DRAWINGS

FIG. 1 shows an atomistic view of the filled skutterudite crystal structure.

FIG. 2 shows a typical melt spinning system.

FIG. 3 is a schematic which illustrates the process of spark plasma sintering (SPS).

FIG. 4A graphically illustrates a series of powder X-ray diffraction (XRD) patterns which provide the X-ray intensity as a function of 2θ for CeFe₄Sb_{11.85} samples Q19-4, Q19-5, and Q19-6 which were melt-spun under different cooling rates.

FIG. 4B shows a typical time-temperature-transformation diagram.

FIG. 4C shows a typical transmission electron microscopy (TEM) image of a melt-spun sample.

FIG. 5A shows a typical optical image of a CeFe₄Sb_{11.85} sample formed by SPS.

FIG. 5B is a plot of the intensity of the diffracted X-ray signal as a function of 2θ for a CeFe₄Sb_{11.85} sample which was subjected to SPS.

FIG. 6A graphically illustrates a plot of the resistivity p as a function of temperature T for CeFe₄Sb₁₂ sintered by SPS at T_{SPS}=585° C. and 630° C.

FIG. 6B graphically illustrates a plot of the thermal conductivity K as a function of temperature T for CeFe₄Sb₁₂ sintered by SPS at T_{SPS}=585° C. and 630° C.

FIG. 6C graphically illustrates a plot of the figure of merit ZT as a function of temperature T for CeFe₄Sb₁₂ sintered by SPS at T_{SPS}=585° C. and 630° C.

FIG. 6D graphically illustrates a plot of the Seebeck coefficient S as a function of temperature T for CeFe₄Sb₁₂ sintered by SPS at T_{SPS}=585° C. and 630° C.

FIG. 7A shows a plot of the resistivity ρ as a function of temperature T for CeFe₄Sb_{12.04} and CeFe₄Sb_{11.85} samples.

FIG. 7B shows a plot of the thermal conductivity κ as a function of temperature T for CeFe₄Sb_{12.04} and CeFe₄Sb_{11.85} samples.

FIG. 7C shows a plot of the figure of merit ZT as a function of temperature T for CeFe₄Sb_{12.04} and CeFe₄Sb_{11.85} samples.

FIG. 7D shows a plot of the Seebeck coefficient S as a function of temperature T for CeFe₄Sb_{12.04} and CeFe₄Sb_{11.85} samples.

FIG. 8A shows a plot of the resistivity p as a function of temperature T for CeFe₄Sb₁₂ which has been processed using an intermediate grinding step.

FIG. 8B shows a plot of the thermal conductivity κ, as a function of temperature T for CeFe₄Sb₁₂ which has been processed using an intermediate grinding step.

FIG. 8C shows a plot of the figure of merit ZT as a function of temperature T for CeFe₄Sb₁₂ which has been processed using an intermediate grinding step.

FIG. 8D shows a plot of the Seebeck coefficient S as a function of temperature T for CeFe₄Sb₁₂ which has been processed using an intermediate grinding step.

FIG. 9A shows a plot of the resistivity p as a function of temperature T for CeFe₄Sb₁₂ which has been processed using an intermediate ball milling step.

FIG. 9B shows a plot of the thermal conductivity κ as a function of temperature T for CeFe₄Sb₁₂ which has been processed using an intermediate ball milling step.

FIG. 9C shows a plot of the figure of merit ZT as a function of temperature T for CeFe₄Sb₁₂ which has been processed using an intermediate ball milling step.

FIG. 9D shows a plot of the Seebeck coefficient S as a function of temperature T for CeFe₄Sb₁₂ which has been processed using an intermediate ball milling step.

FIG. 10 shows powder XRD patterns which provide the X-ray intensity as a function of 2θ for (a) melt-spun CeFe₄Sb₁₂ ribbons and (b) non-equilibrium processed CeFe₄Sb₁₂ samples after SPS; the inset shows (c) an image of typical as-obtained melt-spun ribbons and (d) a high-resolution TEM (HR-TEM) image of a melt-spun ribbon showing a nanocrystal embedded in an amorphous matrix.

FIG. 11A is a scanning electron microscopy (SEM) image showing a freshly fractured surface of a non-equilibrium processed CeFe₄Sb₁₂ sample.

FIG. 11B is a SEM image of a conventionally processed CeFe₄Sb₁₂ sample.

FIG. 11C is a magnified SEM image obtained from the area denoted by the white rectangular box in FIG. 11A.

FIG. 11D is a low-magnification TEM image of the non-equilibrium synthesized CeFe₄Sb₁₂ sample.

FIG. 12A is a low-magnification TEM image showing a number of grains and grain boundaries in a non-equilibrium CeFe₄Sb₁₂ sample.

FIG. 12B is a HR-TEM image obtained from the area denoted by the white square box in FIG. 12A which shows a close-up view of a grain boundary in a non-equilibrium CeFe₄Sb₁₂ sample.

FIG. 12C is a low-magnification TEM image showing typical grains and grain boundaries in a conventionally synthesized CeFe₄Sb₁₂ sample.

FIG. 12D is a HR-TEM image obtained from the area denoted by the white square box in FIG. 12C which shows a close-up view of a grain boundary in a conventionally synthesized CeFe₄Sb₁₂ sample.

FIG. 13 shows XRD patterns which provide the X-ray intensity as a function of 2θ for the filled skutterudite Ce_{0.9}Fe₃CoSb₁₂ which has been prepared by (a) non-equilibrium melt-spinning (MS) and (b) equilibrium annealing (AN) synthesis routes.

FIG. 14A is a SEM image showing the fracture surface of a Ce_{0.9}Fe₃CoSb₁₂ sample which has been produced by a non-equilibrium MS synthesis route.

FIG. 14B is a SEM image showing the fracture surface of a Ce_{0.9}Fe₃CoSb₁₂ sample which has been produced by a conventional equilibrium AN synthesis route.

FIG. 15A shows a plot of the resistivity ρ as a function of temperature T for Ce_{0.9}Fe₃CoSb₁₂ samples which have been initially processed by melt spinning (solid squares) and annealing (open circles) followed by SPS.

FIG. 15B shows a plot of the Seebeck coefficient S as a function of temperature T for Ce_{0.9}Fe₃CoSb₁₂ samples which have been initially processed by melt spinning (solid squares) and annealing (open circles) followed by SPS.

FIG. 15C shows a plot of the power factor as a function of temperature T for Ce_{0.9}Fe₃CoSb₁₂ samples which have been initially processed by melt spinning (solid squares) and annealing (open circles) followed by SPS.

FIG. 16A shows a plot of the thermal conductivity K as a function of temperature T for Ce_{0.9}Fe₃CoSb₁₂ samples which have been initially processed by melt spinning (solid squares) and annealing (open circles) followed by SPS.

FIG. 16B shows a plot of the lattice thermal conductivity κ_{L} as a function of temperature T for Ce_{0.9}Fe₃CoSb₁₂ samples which have been initially processed by melt spinning (solid squares) and annealing (open circles) followed by SPS.

FIG. 16C shows a plot of the figure of merit ZT as a function of temperature T for Ce_{0.9}Fe₃CoSb₁₂ samples which have been initially processed by melt spinning (solid squares) and annealing (open circles) followed by SPS.

FIG. 17 shows a typical thermoelectric device formed from n- and p-type thermoelectric elements.

### DETAILED DESCRIPTION

These and other objectives of the invention will become more apparent from the following description and illustrative embodiments which are described in detail with reference to the accompanying drawings. Similar elements in each Figure are designated by like reference numbers and, hence, subsequent detailed descriptions thereof may be omitted for brevity. In the interest of clarity, the following terms and acronyms are defined as provided below.

### ACRONYMS

BCC: Body Centered Cubic
EDS: Energy Dispersive Spectroscopy
HR-TEM: High-Resolution Transmission Electron Microscopy
PGEC: Phonon-Glass Electron-single-Crystal
SEM: Scanning Electron Microscopy
SPS: Spark Plasma Sintering
TEM: Transmission Electron Microscopy
TTT: Time-Temperature-Transformation
XRD: X-Ray Diffraction
ZT: Figure of Merit

### DEFINITIONS

θ: Used to represent the angle of incidence during X-ray diffraction measurements. The results are typically plotted showing the X-ray intensity as a function of 2θ.
Actinide: The row of chemical elements that lie between and include actinium (Ac) and lawrencium (Lr) in the periodic table with atomic numbers between 89 and 103, respectively.
Alkaline-Earth: The series of chemical elements included in column 2 of the periodic table, including beryllium (Be), magnesium (Mg), calcium (Ca), strontium (Sr), barium (Ba), and radium (Ra).
Acceptor: A dopant atom which, when added to an inorganic semiconductor, can form p-type regions.
Donor: A dopant atom which, when added to an inorganic semiconductor, can form n-type regions.
Im3: International short symbol of a specific space group for a crystal with body centered cubic symmetry.
κ The thermal conductivity is determined through the expression κ=κₑ+κ_{L} where κₑ and κ_{L} are the electron and lattice contribution to the thermal conductivity, respectively.
Lanthanide: The row of chemical elements that lie between and include lanthanum (La) and lutetium (Lu) in the periodic table with atomic numbers between 57 and 71, respectively.
n-type: A semiconductor for which the predominant charge carriers responsible for electrical conduction are electrons. Normally, donor impurity atoms give rise to the excess electrons.
Power Factor The power factor is defined by the expression S²σ.
p-type: A semiconductor for which the predominant charge carriers responsible for electrical conduction are holes. Normally, acceptor impurity atoms give rise to the excess holes.
Pnictide: An element from group V of the periodic table which includes nitrogen (N), phosphorous (P), arsenic (As), antimony (Sb), and bismuth (Bi).
ZT: Figure of merit for thermoelectric materials. Its value is determined by the expression

$$ZT = \frac{{S}^{2} σ T}{κ}$$

where:
S=Seebeck coefficient,
σ=electrical conductivity,
κ=thermal conductivity, and
T=absolute temperature.

This specification describes processes for the non-equilibrium synthesis of high performance thermoelectric materials and provides a plurality of examples of thermoelectric materials fabricated using this process. The manufacturing process is unique in that it exploits phase and microstructural control attainable with fabrication routes which occur far from thermodynamic equilibrium. The use of extremely rapid cooling and sintering rates kinetically inhibits phase segregation and grain growth, thereby providing additional control parameters which greatly expand the regime over which the microstructure may be controlled. The improved microstructural control arises from the combination of steps performed and the ranges of temperature, pressure, and time used. Throughout this specification, focus will be given primarily to the non-equilibrium synthesis of filled skutterudites. It is to be understood, however, that the process is not limited to materials having this specific crystal structure and chemical composition. Any material whose thermoelectric properties may be improved through growth under the kinetically limited conditions disclosed and described in this specification may be contemplated and used.

### I. Skutterudite Crystal Structure

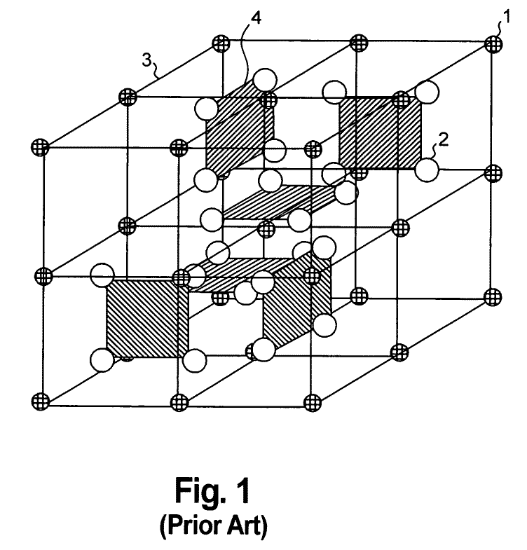

The skutterudite crystal structure is a cubic crystal containing 32 atoms per unit cell. An exemplary schematic of the basic unit cell (100) for the skutterudite crystal structure is shown in FIG. 1. The skutterudite structure belongs to the body centered cubic (BCC) space group Im3 and consists of metal atoms (1) which are assembled into a cubic lattice (3). The unit cell (100) in FIG. 1 comprises eight cubic subcells located adjacent to each other along their individual sides. Each subcell comprises a metal atom (1) at each of the eight corners which constitute the subcell. Six of the eight subcells include a nearly square four-member planar ring (4) defined by the presence of a pnictide atom (2) located at each of its four corners. Each planar ring (4) is parallel to a side of the unit cell and all planar rings (4) are mutually orthogonal. Within a typical skutterudite unit cell (100) each pnictide atom (2) has two neighboring pnictide atoms (2) and two adjacent metal atoms (1) whereas individual metal atoms (1) are each bordered by six adjacent metal atoms (1).

FIG. 1 shows that each unit cell (100) consists of eight metal atoms M (1) and twenty-four pnictide atoms X (2), yielding the general formula MX₃ for a binary skutterudite. Since there are planar rings (4) located within six of the eight subcells defining the unit cell (100), two of the subcells will typically be empty. In FIG. 1, the empty subcells comprise the upper left subcell positioned in the front of unit cell (100) and the bottom right subcell situated in the back of unit cell (100). The empty subcells have a cavity or void located in their center; filled skutterudites have “filler” atoms added to a number of these voids to create phonon scattering centers. Conventional binary skutterudites typically have voids large enough to contain one or possibly even three filler atoms, but most of the time different filler atoms fill different voids. Filled skutterudites have the general formula LnT₄Pn₁₂ for a half unit cell where Ln represents an alkaline earth or rare earth element such as may be found from the lanthanide or actinide series of elements, T is a transition metal, and Pn is a pnictide. In cases where the void is filled by more than one atom, the filler atoms can be a combination of several different elements at any ratio.

Although, in theory, the addition of a filler atom to skutterudites results in materials resembling an ideal phonon-glass electron-single-crystal (PGEC), in reality, thermodynamic considerations place practical limitations on their fabrication. For example, simply adding the desired quantity of a rare earth metal to a binary skutterudite composition while melting at elevated temperatures and cooling under equilibrium conditions does not typically produce the crystal structure of FIG. 1 with filler atoms of the rare earth metal located in the subcell voids. Rather, the material system attempts to lower its overall free energy by, for example, nucleating secondary phases at sites which present a smaller barrier to nucleation such as at grain boundaries or at defects present in the crystal structure. In this case, rather than yielding a filled skutterudite, processing at near-equilibrium results in a low-performance material (from a thermoelectric standpoint) having an undesirable mixture of phases and structures. Producing a filled skutterudite which behaves more like a PGEC therefore requires the development of innovative materials processing schemes which provide additional control over microstructure formation by, for example, introducing processing routes which kinetically limit phase segregation and grain growth.

### II. Kinetically Limiting Cooling Rates

By cooling a material from the melt at extremely high cooling rates typically on the order of, for example, 10⁵ to 10⁷ K/s (one hundred thousand to ten million degrees Kelvin per second) or 10⁶ to 10⁷ K/s (one million to ten million degrees Kelvin per second), the transformation from a liquid to a solid occurs extremely quickly causing the amorphous phase to be essentially “frozen in.” Such rapid cooling rates may be used to expand the accessible phase space by kinetically inhibiting the formation of undesirable phases or precipitates. Since the transformation from the liquid to solid phase occurs very quickly, atoms within the melt do not have sufficient time to migrate to equilibrium or low-energy positions within the crystal lattice to form precipitates or secondary phases. This provides greater control over the resulting structures. When a melt containing a skutterudite in combination with one or more types of filler atoms is cooled from the liquid phase at a very high rate, there is a greater probability that the filler atoms will be incorporated into a larger fraction of the voids in the skutterudite crystal structure during subsequent processing steps. The solid particles formed by rapid cooling from the melt generally have a significant amorphous fraction with additional non-equilibrium processing being necessary (described in Sections III-IV below) for conversion to the crystalline phase.

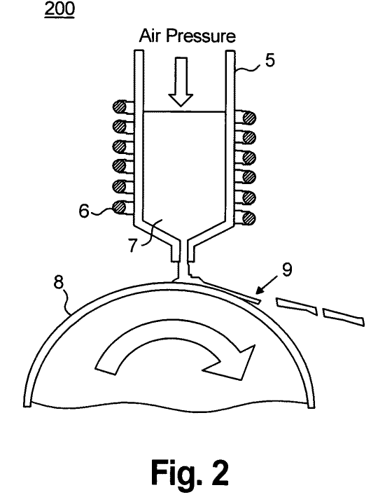

Any technique which is capable of yielding the rapid cooling rates necessary to inhibit phase segregation or nucleation of precipitates may be used. Examples include, but are not limited to melt-spinning, splash quenching, and thermal spraying. The method is not limited to a particular cooling apparatus or technique; the key aspect is the use of an extremely high cooling rate to solidify a liquid melt having the desired composition. In one embodiment, the cooling rate is generally greater than or equal to 10⁵ K/s and in another embodiment the cooling rate is greater than or equal to 10⁶ K/s. However, the cooling rate is not limited to these particular values, being dependent upon the particular material system being processed. In one embodiment rapid cooling is accomplished using a process known as melt spinning. Melt spinning involves directing a stream of the molten alloy onto a cooled wheel rotating at a very high angular velocity. The melt spinning apparatus (200) and its method of operation are illustrated in FIG. 2. Here, a crucible (5) containing a mixture of elements or compounds which will constitute the thermoelectric material is heated using an induction heating coil (6). Once the mixture reaches a temperature high enough to produce a uniformly mixed molten alloy (7), an inert gas such as argon (Ar) is introduced into the crucible (5) to produce internal pressure which forces the molten alloy (7) through an orifice located at the bottom of the crucible and onto the periphery of a rapidly rotating wheel that can reach a linear speed of over 40 m/s at the surface of the wheel (8). The rotating wheel (8) is typically constructed from a material having a high thermal conductivity such as copper (Cu) and is cooled internally and/or externally by water or liquid nitrogen. When the stream of molten alloy impinges onto the rotating wheel (8) it quickly solidifies into a thin, melt-spun ribbon (9) which is ejected along a tangent.

The melt spinning process can be varied through changes in a number of parameters. These include, but are not limited to, the spinning rate of the rotating wheel (8), the amount and type of cooling applied to the rotating wheel (8), the initial temperature of the molten alloy (7), the partial pressure applied, the stream diameter, flow rate of the molten alloy (7), diameter of the rotating wheel (8), as well as the shape (e.g. solid or circular) and dimensions of the orifice. Melt spinning is usually performed under an inert atmosphere, but is not so limited, and typically is capable of attaining cooling rates ranging from 10⁴ to 10⁷ K/s and yields extremely thin ribbon-shaped specimens which can be collected for further processing. Fabrication of solid structures from the melt-spun ribbon (8) typically requires that the pieces constituting the ribbon (8) be compacted into a mold having the desired shape where it is then subjected to further processing. Intermediate processes such as mechanical grinding or attrition in a ball mill may be used to convert the ribbon (8) to a powder having the desired particle shape and size distribution.

In another embodiment the molten alloy may be cooled using a technique analogous to melt spinning as described with reference to FIG. 2, but which has one notable difference. Rather than being poured onto the outer periphery of a rotating wheel, the molten liquid stream may be poured directly onto the center face of a cooled and rapidly rotating disc. This causes small droplets of the molten alloy to be flung tangentially outward in a disc-shaped pattern due to centrifugal forces. This process also facilitates rapid cooling with the solidified product being a fine powder rather than a thin ribbon. The drawback of this process is that it is more difficult to maintain efficient cooling of the rotating disc since its center is exposed to a continuous stream of hot liquid. It may, however, still be possible to obtain cooling rates sufficient to provide the desired microstructural control.

Still another process involves the use of a melt-spinning apparatus such as those produced by Fuisz Technologies, Ltd. and disclosed in, for example, in U.S. Pat. Nos. 6,116,880; 5,779,946; and 5,346,377 which are incorporated by reference as if fully set forth in this specification. Other techniques such as splash quenching in which the liquid is directly poured onto a large conductive block such as copper plate may be used. This technique can also achieve a certain degree of rapid cooling, but generally at a substantially lower cooling rate.

### III. Sintering Processes

Embodiments describing methods of sintering the melt-spun particles formed from cooling under extremely rapid cooling rates as described in Section II above will now be described in detail. Sintering is generally described as a process in which a solid object is formed from particles (e.g., a powder) of a material by heating to a temperature below its melting point. Sintering reduces the porosity and improves the mechanical integrity of the powder aggregate through coalescence of individual particles. Generally, a measured quantity of a powder is compacted into a mold having the desired shape such that a majority of the particles are in contact with a plurality of other particles. During the initial sintering stage there is a net flow of atoms towards contact regions between particles. This produces a neck connecting the particles with a grain boundary being located within the neck. As the neck expands with continued sintering, the pores located between particles gradually become smaller and more spherical. With still further sintering there is a gradual decrease in porosity and a concomitant increase in the grain size as the powder particles coalesce. Heating to a predetermined temperature for a prescribed time period may be used to produce a sintered product having the desired grain size, density, and porosity.

There are a number of variations which may be applied to the sintering process. For example, hot pressing involves the application of a force to compact the particles during sintering. During hot pressing, both pressure and heat are applied simultaneously such that the aggregate is compacted at elevated temperatures. The compaction may be performed using, for example, a press which applies pressure along a single axis. In another embodiment pressure may be applied isostatically by immersing the mold in a liquid and then pressurizing the liquid. In this manner pressure is applied evenly across all surfaces of the mold. Hot pressing is particularly useful for materials having a very high melting point or in instances where it is desirable to produce a material having a high density with minimal grain growth.

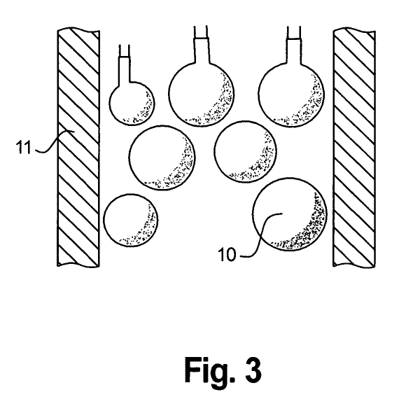

In still another embodiment sintering may be accomplished by a process known as spark plasma sintering (SPS) which will be described with reference to FIG. 3. FIG. 3 is a schematic drawing illustrating the processes occurring during SPS. During SPS, the particles (10), which are typically in powder form, are compacted into a mold (11) having the desired shape. The mold (11) is generally fabricated from an electrically conductive material which is relatively inert and is capable of withstanding elevated temperatures. A common material used for this purpose is graphite. While conventional sintering processes such as hot pressing use an external source to apply heat to the sample, during SPS heat is generated internally.

SPS involves the application of a pulsed direct current (DC) which passes directly through the mold (11) and, in the case of conductive samples, through the particles (10) as well. The flow of current through the mold (11) and powder particles (10) is exemplified by the arrows in FIG. 3. The electrical current heats the powder through Joule heating, a process which is capable of producing very high heating and cooling rates of up to 1,000 K/min. The sintering process may be aided by the generation of an electrical discharge or spark between individual particles. The extremely high heating and cooling rates during SPS permit rapid sintering of the sample with minimal coarsening of particles. This permits the rapid densification of powders into a solid having grain sizes on the nanoscale. Depending on the specific processing parameters used, with SPS the sintering stage may be completed in only a few minutes.

### IV. Non-Equilibrium Synthesis

Exemplary embodiments of processes in which the nonequilibrium synthesis routes described in Sections II and III are performed sequentially to form a thermoelectric material with improved conversion efficiency will now be described. The process described in this Section uses melt spinning and SPS as exemplary methods of obtaining the rapid cooling and sintering rates required for the nonequilibrium synthesis of high efficiency thermoelectric materials. Initially, a mixture containing a predetermined ratio of compounds and/or elements Which will constitute the thermoelectric material are combined in the quartz or boron nitride crucible (5) of a melt spinning apparatus (200) analogous to that illustrated in FIG. 2. The mixture is heated using induction heating coils (6) until the entirety of the mixture is melted and a homogeneous molten alloy (7) is formed.

The interior of the crucible (5) is pressurized with an inert gas and the melt is forced out through an orifice at the bottom of the crucible (5) at a rate which depends on the inert gas pressure and the size of the orifice. During the initial melting process no pressure is applied to the melt. The molten liquid will wet the internal wall of the crucible and surface tension will hold the liquid inside the crucible. This prevents the molten alloy from flowing out through the small orifice. Once the molten liquid has been thoroughly mixed as a result of internal motion occurring due to inductive heating, pressure is applied from the top of the crucible to force the liquid through the orifice. The flowing speed of streaming liquid is proportional to the pressure applied. Precise control of pressure is necessary to produce a good match between the flowing speed of the liquid and the speed of rotating wheel. Unmatched operation will produce either uneven cooling of ribbons when the liquid flow rate is too high, or a lower cooling rate of the ribbon when the liquid flow rate is too low.

Typical inert gases which may be used include nitrogen (N₂) and elements in column VIII of the periodic table which includes, but is not limited to, helium (He), neon (Ne), argon (Ar), and krypton (Kr). The stream of liquid is directed onto the peripheral surface of a water-cooled wheel (8) which is rotating at a very high angular velocity. The type of coolant used and angular velocity of the wheel (8) may be adjusted to obtain the desired cooling rate. The wheel (8) is typically cooled by the continuous flow of cooling water which enters the wheel (8) through an intake, travels through internal cooling channels, and then exits the wheel (8) through an outlet where it returns to an external cooling system. After contacting the rotating water-cooled wheel (8), the molten alloy (7) quickly solidifies into a thin ribbon (9) which is ejected along a tangent to the point of contact with the wheel (8). The ribbon-like particles created by melt-spinning are gathered and compacted into a mold (11) having the desired size and shape. It is to be understood that the shape and size of the mold (11) may be tailored to any particular application or device. However, for simplicity and for purposes of this specification, the mold (11) exemplified in FIG. 3 is constructed from graphite and is cylindrical in shape with a top and bottom ram, thereby forming a uniaxial press. By filling the mold with the particles (10) produced by melt-spinning and compressing the sample using the top and bottom ram, a thin disc-shaped or a long cylinder-shaped specimen may be formed. A short sintering time of a few minutes is generally desirable to prevent grain growth. This is also the minimum time necessary to convert the ribbon-like materials into a fully crystalline material.

In some embodiments, the melt-spun ribbon (9) may be subject to mechanical grinding or attrition in a ball mill to further reduce the size of the particles and/or produce a more uniform distribution of particles. The grinding or milling step may be accomplished using standard equipment and processes which are well-known in the art. Sintering of the compressed disc-shaped specimens is performed using SPS under uniaxial compression. During the sintering stage, a mechanical force is applied to compress the sample while a pulsed DC current is allowed to pass directly through the sample and mold. The amount of force applied, the duration and intensity of each pulse, as well as the overall sintering time are set based on the end-product desired. Each parameter provides a control knob which can be adjusted to vary the microstructure of the resulting sintered product.

Exemplary embodiments in which CeFe₄Sb₁₂ or Ce_{0.9}Fe₃CoSb₁₂ are produced by melt spinning followed by SPS are described in the examples that follow. In these examples, the electrical resistivity (and, hence, the conductivity) of each sample is measured using a four-point probe on slabs having dimensions of, for example, 0.3×1.0×12 mm. The thermal conductivity and Seebeck coefficient are obtained using two- and four-probe measurements on samples having dimensions of, for example, 1×1×2.5 mm. As the results provided in Examples 1-7 show, samples synthesized by non-equilibrium routes generally have a smaller grain size and cleaner grain boundaries than samples prepared by conventional solid-state reactions and long-term annealing processes. While a smaller grain size may help lower the lattice thermal conductivity, cleaner grain boundaries help to ensure a higher carrier mobility and, subsequently, a higher electrical conductivity at typical application temperatures.

### Example 1

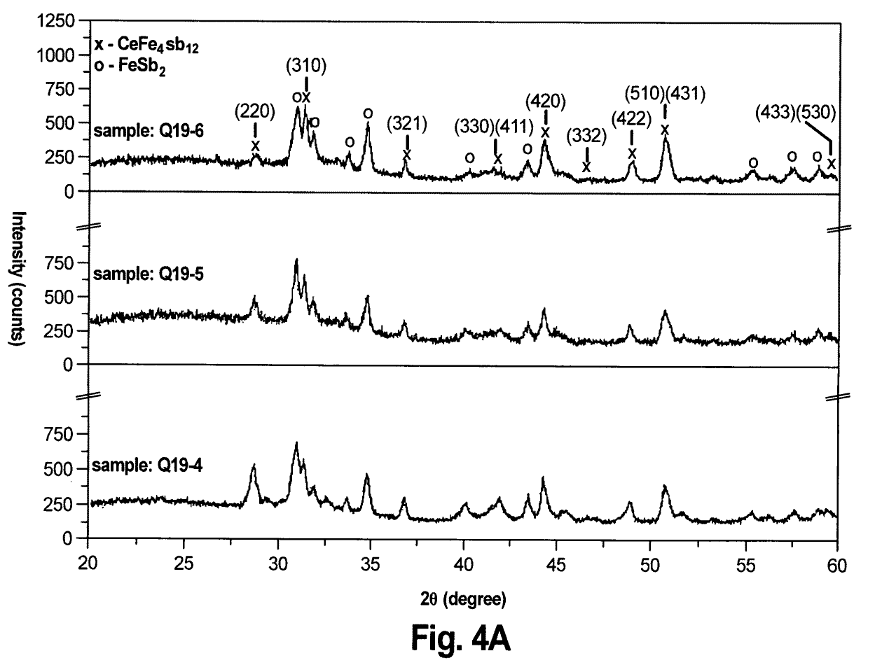

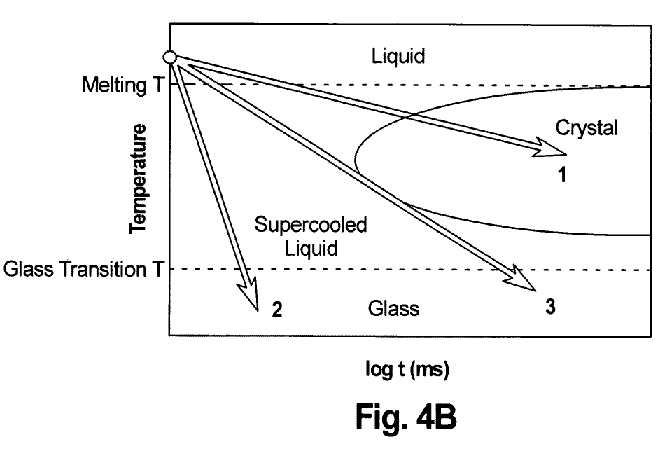

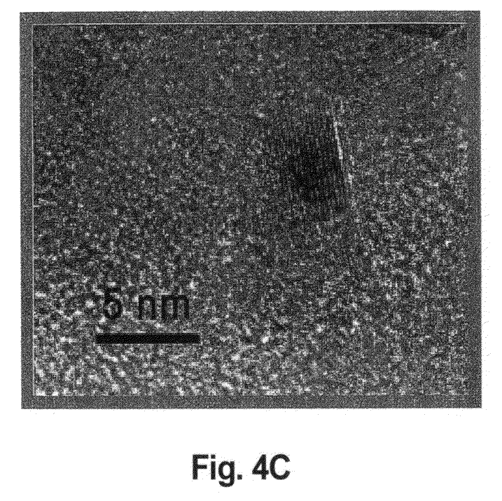

A predetermined quantity of Ce, Fe, and Sb is mixed together in the crucible of a melt-spinning apparatus. The ratio of Ce, Fe, and Sb present is nominally 1:4:12 such that it corresponds to the chemical formula for CeFe₄Sb₁₂. The mixture is heated to a temperature in excess of 1100° C. under an Ar gas ambient and held for a duration sufficient to completely melt all constituents and produce a uniformly mixed molten alloy. The Ar gas pressure is increased by ⅓ of the atmospheric pressure (atm), and a thin stream of molten alloy is ejected from the crucible through a 0.5 to 1.0-mm-diameter orifice, where it is directed onto a water-cooled wheel rotating at an angular velocity of 40 to 70 rpm (rotations per minute). The resulting melt-spun ribbons were analyzed using powder X-ray diffraction (XRD), as shown in FIG. 4A. Two additional melt-spun samples were fabricated under different melt-spinning conditions to serve as a basis for comparison and are also shown in FIG. 4A. From top to bottom in FIG. 4A, the XRD patterns correspond to melt-spun samples obtained at wheel rotation speeds of 70, 50, and 40 rpm. The time from when the liquid first touches the copper wheel to the end of the flow is approximately 0.1 to 8 seconds for 1 to 100 grams of sample. In another exemplary embodiment, a sample size of 20 grams is melt spun in approximately 2 seconds. Plan-view transmission electron microscopy (TEM) images of the results are provided in FIG. 4C, which shows a nano-scaled crystal embedded in an amorphous matrix.

The melt-spun samples each have the same composition, are identified as samples Q19-4, Q19-5, and Q19-6, and are shown with their corresponding XRD scan in FIG. 4A. The XRD data shows that as the rotating speed decreases, more crystalline phase forms. This is evident from the growing height of the (220) peak in the XRD. Identification of the resulting peaks reveals the presence of two primary crystalline phases which are CeFe₄Sb₁₂ and FeSb₂. The peaks arising from CeFe₄Sb₁₂ are identified with an X whereas peaks associated with FeSb₂ are labeled with an O. The crystallographic plane(s) associated with each CeFe₄Sb₁₂ peak is also identified in FIG. 4A.

FIG. 4B shows a typical time-temperature-transformation (TTT) diagram which indicates the phase space accessible through different cooling rates from the melt. Slow cooling through path 1 results in a fully crystalline material whereas cooling through path 2 or 3 produces a glass-like material. Path 3 generally represents the minimum cooling rate necessary to produce an amorphous material from the melt. The TEM micrograph shown in FIG. 4C, which was obtained from sample Q19-6, shows the presence of an amorphous matrix with nanometer-scale particles distributed throughout.

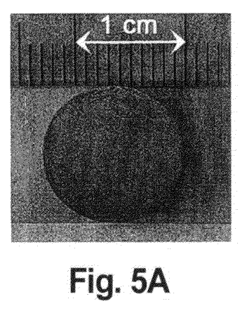

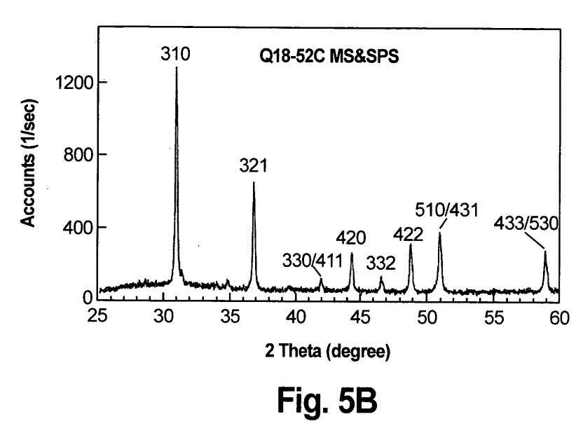

A quantity of particles obtained from melt-spun sample Q19-6 was added to the cylindrical mold (11) of the SPS system described above with reference to FIG. 3. The sample was compacted under a force of F_{SPS}=6.3 kN (kiloNewtons) over an area of about 64 mm² (a circular cross section having a diameter of about 9 mm) and subjected to SPS at a temperature of T_{SPS}=630° C. for 2 min. A photograph of the resulting sintered disc-shaped specimen is provided in FIG. 5A. The disc is approximately 1.25 cm in diameter and has a thickness of 3 mm. The sintered sample was again analyzed by powder X-ray diffraction and the resulting X-ray profile is shown in FIG. 5B. The diffraction profile shows a complete conversion of the ribbon-like material into the single-crystal phase, being marked by a great increase in the intensity of diffraction peaks associated with the CeFe₄Sb₁₂ phase and a concurrent decrease in the number and intensity the of FeSb₂ crystallographic peaks. In fact, the FeSb₂ diffraction peaks are near or below the diffraction limit with the only discernable peaks arising from the presence of FeSb₂ precipitates at approximately 43.5° and 55°, which disappear in the XRD pattern.

The disappearance of FeSb₂ XRD peaks occurs due to the reaction of FeSb₂ with Ce and Sb present in the surrounding matrix constituting the melt-spun ribbon to form CeFe₄Sb₁₂. Sintering for longer time periods will further reduce the amount of FeSb₂ present; however, additional sintering will produce further CeFe₄Sb₁₂ grain growth. A larger grain size will, in turn, reduce the effectiveness of phonon scattering by grain boundaries. It is therefore desirable to balance the inclusion of an acceptable amount of FeSb₂ impurity precipitates (usually less than 1-3 wt. %) which does not influence the electrical properties with a minimal sintering time to avoid excessive grain growth.

The extensive TEM analysis of samples before and after SPS show a small increase in grain size combined with a near complete elimination of FeSb₂ after SPS. These results indicate it is possible to successfully produce dense CeFe₄Sb₁₂ samples with nanometer-scale grain sizes, substantially clean grain boundaries, and minimal phase segregation using non-equilibrium synthesis techniques. The thermoelectric properties of the CeFe₄Sb₁₂ sample formed in Example 1 were measured at room temperature (293-295 K) and are compared to samples with similar compositions in Table 1 below. Comparison Sample 1 was provided by J. Yang at General Motors (GM), using conventional equilibrium solid state synthesis techniques which usually take more than a week while Comparison Sample 2 was reported by J. P. Fleurial, et al using a similar process to that of GM as described by Fleurial, J.-P.; Borshchevsky, A.; Caillat, T.; Morelli, D. T.; Meisner, G. P.; “High figure of merit in Ce-filled skutterudites,” Fifteenth International Conference on Thermoelectrics, 1996, pp. 91-95, 26-29 Mar. 1996. Table 1 shows that the measured figure of merit ZT=0.127 for Example 1 exhibits a 21% improvement over ZT=0.105 for Comparative Sample 1 and a 28% improvement over ZT=0.099 for Comparative Sample 2.

TABLE 1

| Sample | ρ (μΩ · m) | κ (W/K · m) | S (μV/K) | ZT |
|---|---|---|---|---|
| Example 1 | 4.42 | 3.23 | 78.45 | 0.127 |
| Comparative | 5.38 | 2.98 | 76.04 | 0.105 |
| Sample 1 | | | | |
| Comparative | 7.5 | 1.4 | 59 | 0.099 |
| Sample 2 | | | | |

In Examples 2 and 3 below, the sintering temperature and Sb concentration are varied and the effect on the temperature dependence of the resistivity ρ, thermal conductivity κ, Seebeck coefficient S, and figure of merit ZT is analyzed. Examples 4 and 5 provide embodiments in which an intermediate step of grinding or ball milling the melt-spun ribbon is performed.

### Example 2

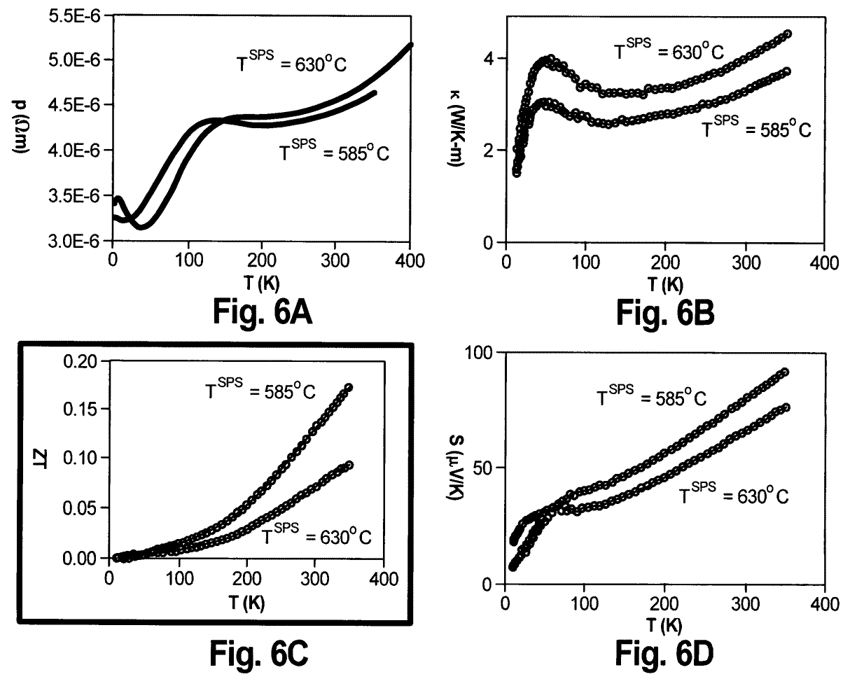

A quantity of Ce, Fe, and Sb substantially identical to that used in Example 1 is mixed together in the crucible of a melt-spinning apparatus and heated above 1100° C. under an Ar gas ambient and held for a duration sufficient to completely melt all constituents and produce a uniformly mixed molten alloy. The Ar gas pressure is again increased by ⅓ atm and a thin stream of molten alloy is directed onto a water-cooled wheel rotating at 40 rpm. A quantity of the melt-spun particles was added to the SPS system and were again compacted under a force of F_{SPS}=6.3 kN (kiloNewtons) on a circular cross section of diameter about 9 mm. However, in this case the particles were sintered at a temperature of T_{SPS}=585° C. for 2 min. The resistivity ρ, thermal conductivity κ, figure of merit ZT, and Seebeck coefficient S for the T_{SPS}=585° C. and 630° C. samples were measured and the results are plotted in FIGS. 6A, 6B, 6C, and 6D, respectively, as a function of temperature. T over the range T=5 K to 350 K. All other synthesis parameters were kept substantially identical while the SPS temperature was varied.

FIG. 6C shows that below approximately 100 K there is a relatively insignificant change in the measured value for the figure of merit ZT measured for CeFe₄Sb₁₂ samples sintered at T_{SPS}=585° C. and 630° C. As the temperature is increased above 100 K, ZT for the T_{SPS}=585° C. sample gradually increases more rapidly than its counterpart at T_{SPS}=630° C. At 350 K, the value of ZT for the T_{SPS}=585° C. sample is approximately twice that for T_{SPS}=630° C. The increase in ZT is attributed primarily to an increase in the Seebeck coefficient S, a reduction in the thermal conductivity κ with a comparatively smaller decrease in the resistivity ρ over this temperature range.

### Example 3

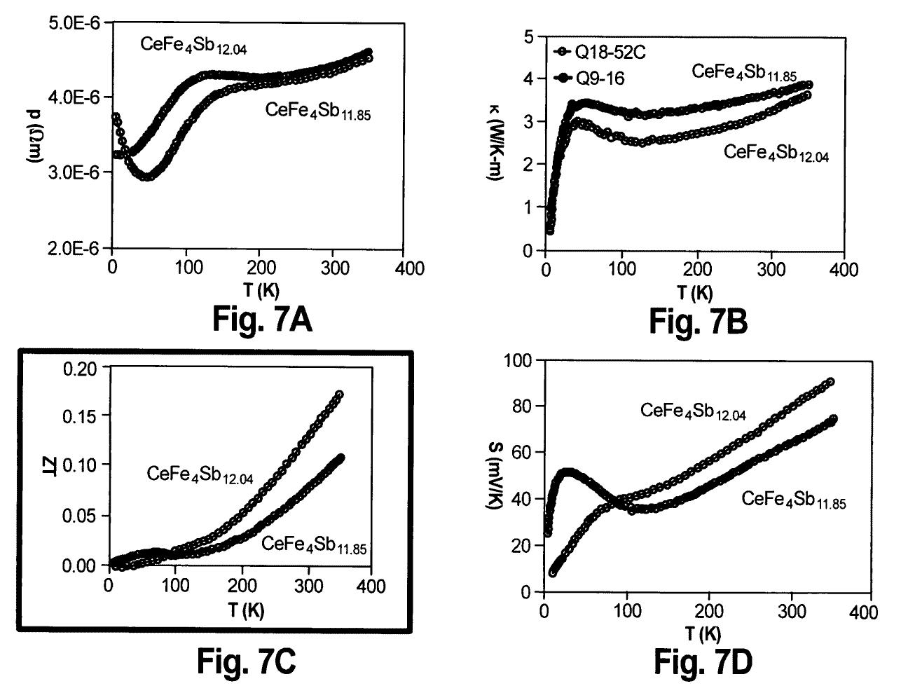

Elemental Ce, Fe, and Sb are mixed together, melted, processed by melt spinning, and then sintered by SPS at T_{SPS}=630° C. with F_{SPS}=6.3 kN on a 9-mm diameter die in substantially the same manner as Example 1. However, for this sample the Sb content is increased slightly such that a sintered sample having atomic concentrations represented by the chemical formula CeFe₄Sb_{12.04} is produced. Thus, the Sb ratio in Example 3 is increased from 11.85 to 12.04 and the thermoelectric properties of these materials are compared in FIGS. 7A-D. FIG. 7C shows that below approximately 100 K, the figure of merit ZT for CeFe₄Sb_{11.85} is slightly higher than for CeFe₄Sb_{12.04}. As the temperature gradually increases, ZT for CeFe₄Sb_{12.04} begins to increase with increasing temperature at a rate greater than that observed for CeFe₄Sb_{11.85}. However, the observed increase in ZT is not as significant as that obtained through a reduction in the sintering temperature T_{SPS} in Example 2. The increase in ZT observed for CeFe₄Sb_{12.04}T>100 K again arises from an increase in the Seebeck coefficient S (FIG. 7D) and a corresponding reduction in the thermal conductivity κ (FIG. 7B) while the resistivity ρ (FIG. 7A) of the CeFe₄Sb_{12.04} sample remains only slightly higher than that of CeFe₄Sb_{11.85}.

In the next two examples, an intermediate grinding or ball milling stage which is performed after melt spinning, but before sintering is introduced. The results are then compared to those of the standard melt spinning and SPS sample from Example 1. One of the potential advantages presented by grinding or ball milling is that it can reduce the size of particles produced by melt spinning and produce a more uniform particle size distribution. In principle this would facilitate more efficient filling of molds and greater densification upon sintering. However, intermediate grinding and ball milling can introduce contamination that is detrimental to the performance of the thermoelectric materials.

### Example 4

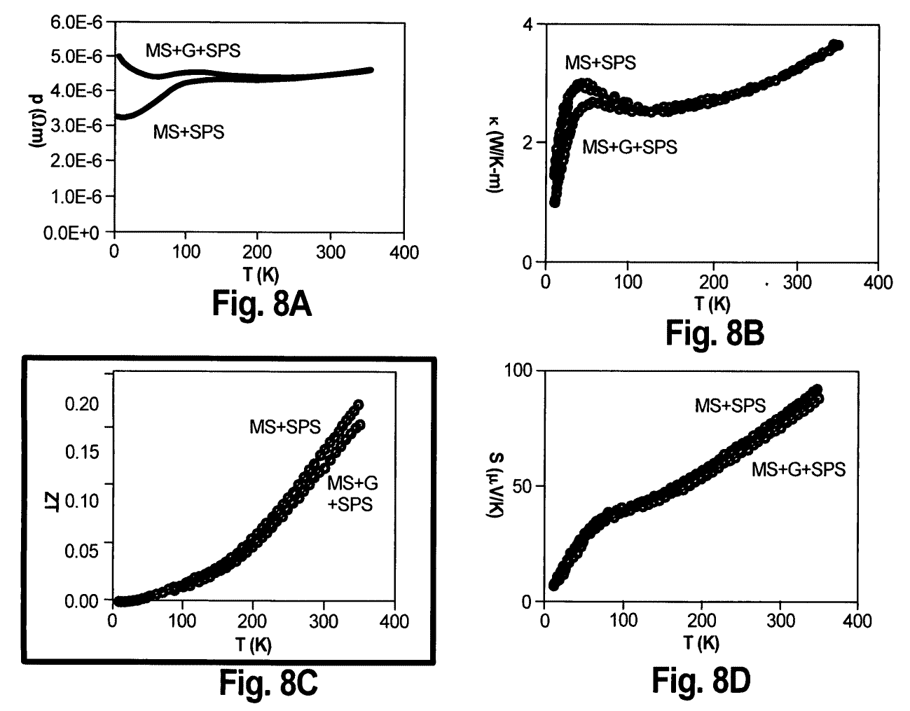

An amount of Ce, Fe, and Sb substantially the same as Example 1 is mixed together, melted and processed by melt spinning. The particles produced by melt spinning are subjected to an intermediate grinding stage in which grinding is performed using mortar and pestle. The intermediate grinding step produces a powder consisting of substantially smaller particles having an average particle size of 20 μm. After grinding, the resulting powder is introduced to the SPS mold and is sintered at T_{SPS}=580-585° C. with F_{SPS}=6.3 kN using a 9-mm die. The resistivity ρ, thermal conductivity κ, figure of merit ZT, and Seebeck coefficient S for the resulting sample were measured as a function of temperature T over the range T=5 to 350 K and the results are plotted in FIGS. 8A, 8B, 8C, and 8D, respectively, along with data from the sample of Example 1. In FIGS. 8A-D, the data points from the sample subjected to an intermediate grinding stage are labeled as “MS+G+SPS” whereas the sample from Example 1 is labeled “MS+SPS.” The data in FIGS. 8A-D shows that an intermediate grinding stage produces minimal change in the thermoelectric properties. In FIG. 8C, there is a small reduction in ZT from 200 to 300 K compared to samples which are not subjected to mechanical grinding. This is primarily due to a reduction in the Seebeck coefficient S over this temperature range.

The results presented in FIGS. 8A-D show that, there was relatively little change in the thermoelectric properties after introducing an intermediate mechanical grinding step. However, this also indicates that it may be possible to convert the melt-spun ribbon into uniformly sized powder particles. In this form, the particles are more suitable for the production of uniform and dense samples using powder metallurgy techniques.

### Example 5

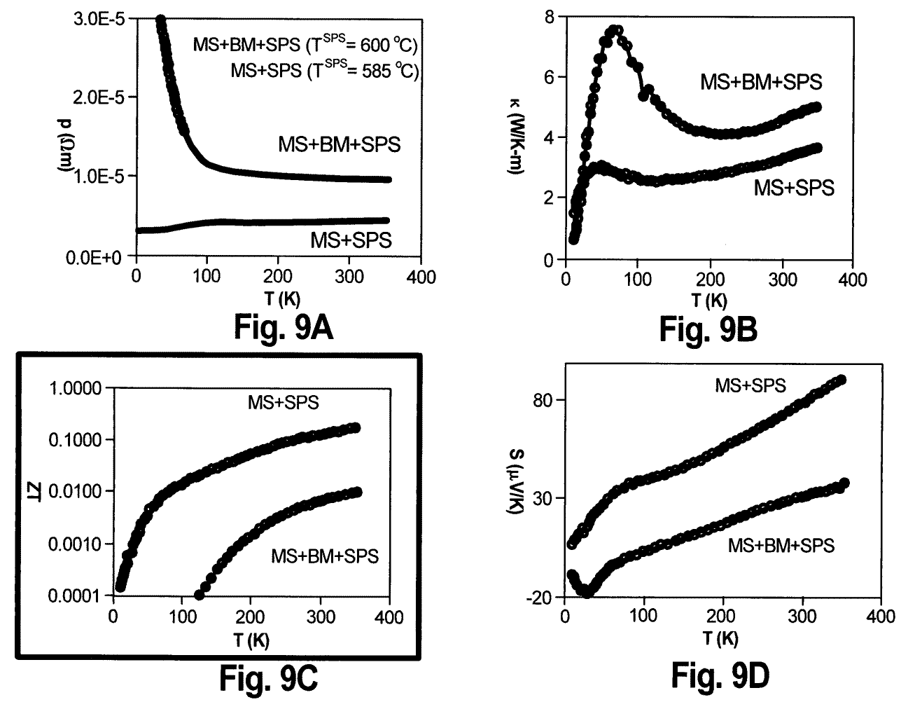

Elemental Ce, Fe, and Sb in substantially the same quantities as Example 1 were mixed together, melted and processed by melt spinning. The particles produced by melt spinning are subjected to an intermediate step in which the melt spun ribbon is subject to attrition in a ball mill. This is accomplished by ball milling for 2 h. The intermediate grinding step produces a powder having substantially smaller particles with a mean particle size of 5 μm. After grinding, a predetermined quantity of the resulting powder is introduced to the SPS mold and is sintered at T_{SPS}=600° C. with F_{SPS}=6.3 kN. The sintering temperature used in this example is approximately 15° higher than that used in Examples 1 and 4 above. The resistivity ρ, thermal conductivity κ, figure of merit ZT, and Seebeck coefficient S for the ball milled samples were again measured and the results are plotted in FIGS. 9A, 9B, 9C, and 9D, respectively, as a function of temperature T over the range T=5 K to 350 K with data from the sample of Example 1 being provided as a basis for comparison. In FIGS. 9A-D, data points from the sample subjected to an intermediate ball milling are labeled as “MS+BM+SPS” whereas the sample from Example 1 is again labeled “MS+SPS.”

The data in FIGS. 9A-D shows that an intermediate ball milling stage is detrimental to the thermoelectric properties of the sintered product. Ball milling increases the resistivity ρ (FIG. 9A) and thermal conductivity κ (FIG. 9B) while lowering the Seebeck coefficient S (FIG. 9D) over the entire measured temperature range. FIG. 9A shows that the measured value of ZT for the MS+BM+SPS sample is nominally zero below approximately 125 K and is more than an order of magnitude less than the MS+SPS sample from 125 to 300 K. These results suggest that the grinding and shearing processes which occur during ball milling modify the microstructure in a manner that lowers its thermoelectric properties. Although the ball milled sample was sintered at a slightly higher temperature(600° C. compared to 585° C. for Example 1), it is unlikely this difference alone is sufficient to account for the difference in material properties. The change in properties observed from lowering T_{SPS} by 45° C. in FIGS. 6A-D is not as significant as that observed in FIGS. 9A-D.

### Example 6

Stoichiometric ratios of high purity Ce (99.8% pure), Fe (99.98% pure) and Sb (99.9999% pure) were loaded into boron nitride (BN) tubes for the synthesis of non-equilibrium CeFe₄Sb₁₂ samples. The BN tubes were then evacuated and refilled with argon (Ar) gas. The raw materials in the BN tubes were melted at about 1450° C. for 30 seconds in an induction furnace, and then allowed to cool to room temperature over 30 minutes. The thus-formed ingots were introduced to a quartz tube having a 0.5-mm-diameter nozzle. Under an Ar ambient, the ingots were melted and injected under an Ar gas pressure of 0.067 MPa onto a copper wheel rotating at a surface linear speed of 30 m/s. The melt-spun CeFe₄Sb₁₂ ribbons were pressed into a pellet and densified by spark plasma sintering (SPS) under a vacuum while applying a pressure of 50 MPa at 600° C. for 2 minutes.

Conventional CeFe₄Sb₁₂ samples were prepared by loading the high purity elemental constituents into a quartz tube having a carbon coating. The quartz tube was evacuated to produce a vacuum and then sealed. The sealed quartz tube was then heated to 600° C. at a rate of 2° C./min, held at 600° C. for 3 h, and then slowly heated to 1050° C. at a rate of 0.5° C./min. After being held at 1050° C. for 30 h, the quartz tube was removed from the furnace and quenched in a water bath. Annealing was then performed at 700° C. for another 30 h. The ingot was removed from the quartz tube, ground to produce a powder, and then pressed into a pellet. Densification by SPS followed the same procedure used for non-equilibrium synthesis.

The composition and phase of the melt-spun ribbons and the sintered bulk samples were determined using a Philips XRG 3100 X-ray diffractometer using Cu Kα radiation (λ=0.15418 nm). A Hitachi S-4800 Scanning Electron Microscope (SEM) was used to characterize the morphologies of fresh fracture surfaces present in the two types of sintered bulk samples. The microstructure of the ribbons and bulk samples, including the grain size, grain boundaries, and types of defects were studied by transmission electron microscopy (TEM) using a JEOL JEM 2100F. TEM samples of melt-spun ribbons were prepared by grinding the brittle ribbons into a very fine powder. A droplet of dilute solution of the fine powders in ethanol alcohol was placed onto a lacey film coated copper grid and allowed to dry. Sintered samples were prepared for TEM analyses using a traditional dimpling method. After mechanically polishing and dimpling to a thickness of about 20 μm, the samples were thinned to electron transparency using an ion mill system at low milling angles (6-12°). The specimen stage of the ion mill system was cooled by liquid nitrogen, which helps avoid local specimen overheating during the milling process in order to eliminate artifacts. All TEM samples were ion milled below −90° C.

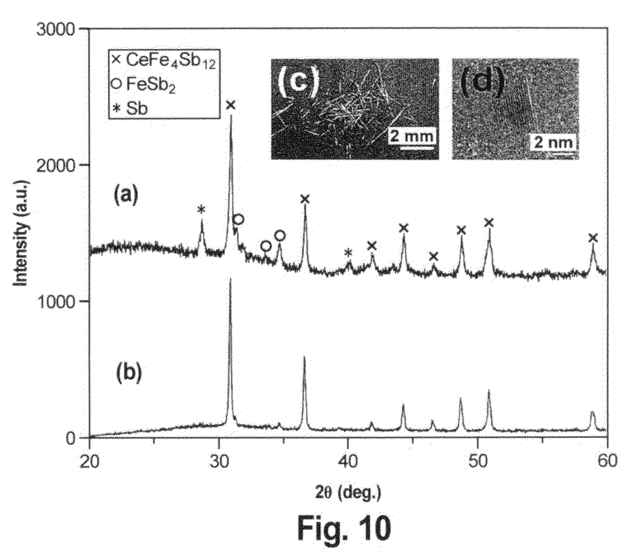

FIG. 10 shows XRD patterns of (a) the melt-spun CeFe₄Sb₁₂ ribbons and (b) the non-equilibrium processed CeFe₄Sb₁₂ sample after SPS. The melt-spun ribbons have characteristic lengths of 5 mm and thicknesses of 15 μm as shown, for example, by image (c) which is provided in the inset of FIG. 10. The reflection peaks in X-ray spectra (a) are indexed to the CeFe₄Sb₁₂ phase with small amount of FeSb₂ and Sb. All peaks are broadened due to the ultra fine grains and amorphous phase formed during the melt spinning process. The HR-TEM image shown as image (d) in the inset of FIG. 10 shows a 5-nm grain embedded in the amorphous matrix; this is consistent with the XRD results obtained in (a). The XRD pattern of the non-equilibrium sintered sample (b) shows sharp reflection peaks and is indexed as substantially the CeFe₄Sb₁₂ phase with trace amount of FeSb₂. Since Sb peaks are not observed in sample (b), this indicates that the materials in the melt-spun ribbons had been fully reacted and crystallized during the very short SPS sintering process.

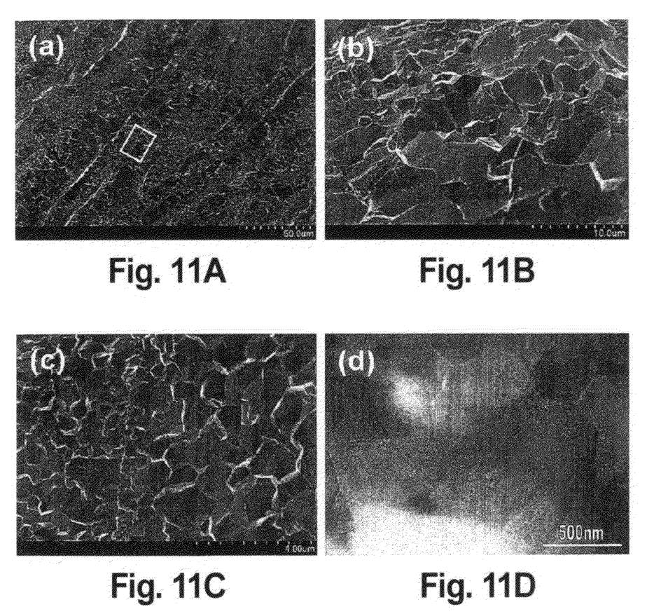

FIGS. 11A and 11B show SEM images of freshly fractured surfaces of the non-equilibrium (11A) and conventionally synthesized (11B) CeFe₄Sb₁₂ samples, respectively. FIG. 11A shows that the non-equilibrium synthesized sample is composed of compact stacking ribbon-like layers perpendicular to the SPS pressure direction. By contrast, FIG. 11B shows that the conventionally processed sample does not have a stacking layer structure and the grain size varies from 1 μm to more than 10 μm. FIG. 11C is a magnified SEM image of the rectangular box area in FIG. 11A, which shows that the grain size distribution ranges from about 100 nm to about 1 μm.

It is likely that during the melt spinning process, the non-uniform cooling rates along the ribbon thickness direction cause variations of crystallite size, resulting in the observed size distribution of grains in the SPS sintered sample. FIG. 11D, which is a low magnification TEM image of the non-equilibrium synthesized sample, shows that the grains are densely packed with clean grain boundaries and no pores. The average grain size of the non-equilibrium synthesized CeFe₄Sb₁₂ sample is around 500 nm, which is about an order of magnitude smaller than the grain size of the conventionally processed sample.

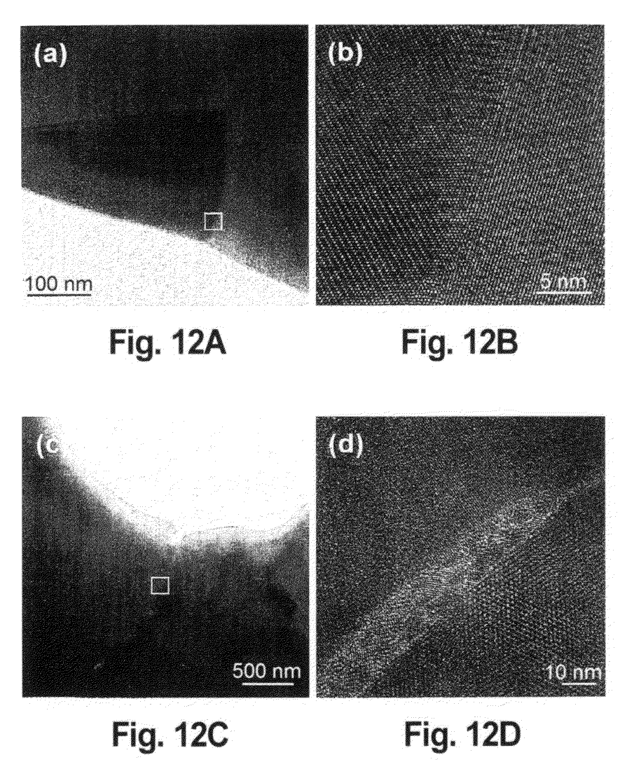

Results from TEM analyses of the samples are provided in FIGS. 12A-D. FIG. 12A shows that the non-equilibrium synthesized CeFe₄Sb₁₂ samples have densely packed grains with most of the grain boundaries being clean and straight. In the conventionally synthesized samples, second phase precipitations are easily found in grain boundaries, an example of which is provided in FIG. 12C. FIGS. 12B and 12D are HR-TEM images obtained from the boxed areas in FIGS. 12A and 12C, respectively, which provide details on the local grain boundary structures at the atomic scale. FIG. 12B shows two well-coupled grains with a structurally intact grain boundary in the non-equilibrium synthesized sample. FIG. 12D shows poorly coupled grains with a second phase present in the boundary of the conventionally prepared sample. The width of the second phase layer in such grain boundaries ranges from 1 to 10 nm.

The atomic percentage of the component elements at the grain boundaries and within the grains of the conventionally synthesized CeFe₄Sb₁₂ was determined using energy dispersive spectroscopy (EDS). The grain boundaries were found to be much more Ce-rich (as much as 5-10 times higher) than within the grains. For example, the Ce:Fe:Sb ratios in two of the grain boundaries are 58.5:1.5:40 and 39.2:8.1:52.7, respectively, while the compositions within each grain are very close to stoichiometric CeFe₄Sb₁₂ with a ratio of 5.9:23.5:70.6.

SEM and TEM characterizations show that CeFe₄Sb₁₂ samples produced by the non-equilibrium route of melt spinning and SPS have nanometer-sized grains and cleaner grain boundaries. This is in marked contrast to the micrometer sized grains and “dirty” grain boundaries in the samples prepared by conventional long term annealing plus SPS. In nanometer-grained samples, the total number of grain boundaries is dramatically increased. Additional phonon scattering by the grain boundaries provides an effective way to further lower the lattice thermal conductivity in the non-equilibrium synthesized samples. Furthermore, cleaner grain boundaries in the non-equilibrium synthesized samples ensure that they scatter phonons effectively while having minimal effect on the transport of charge carriers, thereby resulting in a higher electrical conductivity.

### Example 7

Filled skutterudite ingots were prepared by mixing stoichiometric amounts of high purity Ce (ingot, 99.8% min, Alfa Aesar), Fe (granules, 99.98%, Alfa Aesar), Sb (shots, 99.9999%, Alfa Aesar) and Co (Slug 99.95%, Alfa Aesar). The mixture was sealed in a carbon-coated quartz tube under ⅓ atm of Ar gas. The quartz ampoule was slowly heated to 1050° C. and left at that temperature for 30 h. The quartz ampoule containing the homogenous molten liquid was removed from the furnace at 1050° C. and quenched in a water bath.

A part of a quenched ingot was used to produce melt-spun samples. The surface linear speed of the copper roller was adjusted to 30 m/s. The melt-spun ribbons were ground into a powder, loaded into graphite dies, and sintered under 50 MPa by SPS at 620° C. for 2 minutes. For comparison, another part of the quenched ingot was placed in a furnace and annealed at 700° C. for 30 h to form the single phase compound. This was followed by powdering and SPS sintering using the same pressure, temperature, and time that were used for the melt-spun samples. For ease of reference, the melt-spun and long term annealed pellets are designated as MS and AN, respectively.

X-ray powder diffractometry was performed using a Philips 3100E with Cu K_{α} radiation and was used to investigate the phase formation in the samples. The microstructure of the samples was examined using SEM and TEM. High temperature thermoelectric properties were characterized at the University of Michigan and cross-checked at the High Temperature Materials Laboratory in Oak Ridge National Laboratory (ORNL). In general, the difference in measurements obtained between the two locations is rather small (˜10%). The data collected at ORNL is used in this specification.

The thermopower (i.e., the Seebeck coefficient) from room temperature up to 800 K was measured on a ULVAC ZEM-3 Seebeck Coefficient/Electric Resistance Measuring System. The thermal conductivity (κ) was calculated from the measured thermal diffusivity D, specific heat Cₚ and density d using the relationship κ=DCₚd. The thermal diffusivity D was measured by the laser flash method (ANTER FLASHLINE™ 5000) and the specific heat was determined using a Q2000-DSC TA Instrument. Lattice thermal conductivities (κ_{L}) were obtained by subtracting the electronic contribution (κₑ) from the total thermal conductivity (κ). κₑ was obtained by using the Wiedemann Franz law: κₑ=LTσ, where L is the Lorenz number (a moderate L=2.0×10⁻⁸ WΩK⁻² is used here).

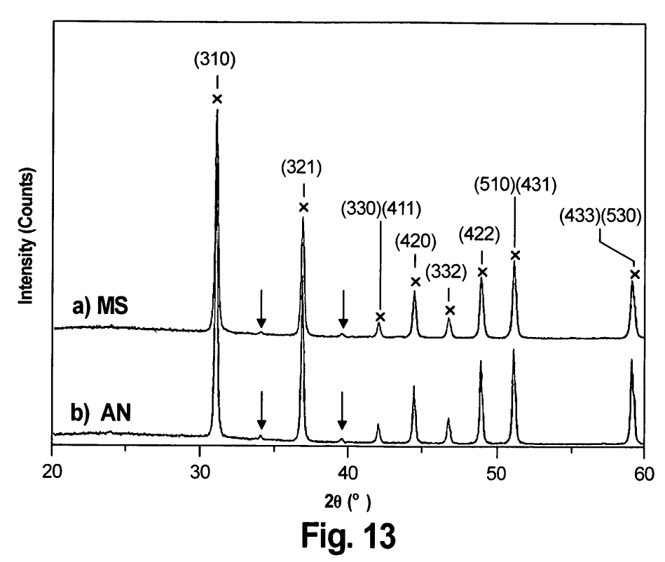

FIG. 13 shows XRD patterns obtained for (a) MS and (b) AN samples, both of which predominantly have the filled skutterudite phase (diffraction peaks marked by X). The XRD pattern for the MS and AN samples appear very similar and a trace amount of Fe(Co)Sb₂ was detected as an impurity in both samples (denoted by the arrows in FIG. 13). The MS samples appear to have a lower impurity content, as evidenced by the lower impurity peaks in the XRD analysis, suggesting that the rapid direct conversion process is very effective. Compared with the conventional solid state reaction and long-term annealing method, the processing time for melt-spinning and SPS was reduced by several orders of magnitude, and is clearly advantageous for cost-saving during industrial production.

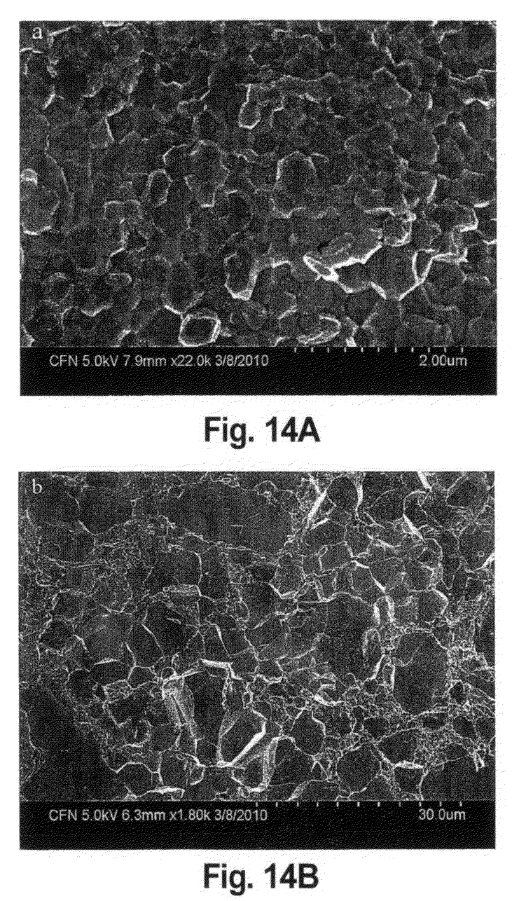

FIG. 14A is a SEM image showing the fracture surface of a MS sample. The sample is very dense and has a very small grain size with clean grain boundaries. The grain size in the MS samples varies from about 150 nm to about 500 nm. The fracture surface of an AN sample is provided in FIG. 14B to serve as a basis for comparison. A comparison of FIGS. 14A and 14B shows that the AN sample has a very large grain size distribution. The smallest grains observed in the AN sample are around 10 μm, approximately two orders of magnitude larger than those in the MS sample. Another observation of the fracture surfaces shown in FIGS. 14A-B is that the fracture surface of the MS sample proceeds through its grain boundaries, while the fracture surface of the AN sample preferentially proceeds through its grains. That means that when a MS sample breaks, the fracture preferentially propagate along its grain boundary. Usually, a material with this characteristic has a better fracture strength due to the larger amount of energy needed for a crack to propagate around grains rather than cutting though grains.

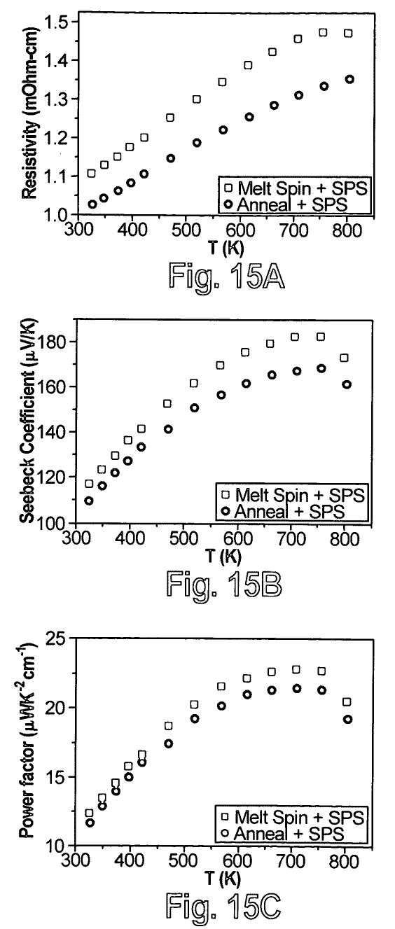

The temperature dependences of the resistivity ρ, Seebeck coefficient S, and the power factor (defined as S²σ) for the AN and MS samples are provided in FIGS. 15A-C. Both the AN and MS sample exhibited metallic conductivity; however, the MS sample was found to have a highter ρ. This may have been due, at least in part, to the smaller grain size present in the MS sample. The MS sample also exhibited a higher S over the entire temperature range investigated. This results in a ˜10% higher power factor compared to the AN sample. A similar power factor enhancement has been reported in a Si_{0.8}Ge_{0.2}B_{0.016} nanocomposite material and was explained as being a result of strong interface scattering which likely alters the energy dependence of the electron scattering rate.

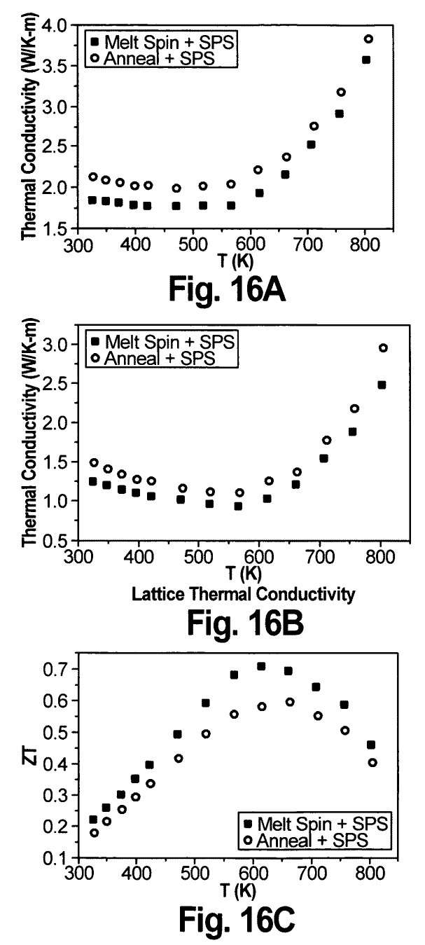

FIGS. 16A, 16B, and 16C display the temperature dependence of the thermal conductivity κ, κ_{L}, and figure of merit ZT, respectively, for the AN and MS samples. The total thermal conductivity κ is given by κ=κₑ+κ_{L} where κₑ and κ_{L} are the electron and lattice contribution to the thermal conductivity, respectively. The electronic contribution (κₑ) to the total thermal conductivity is about 25%. Compared to the AN samples, the total κ of MS sample is reduced by 20% at room temperature and by 10% at 800 K. Interestingly, FIG. 16B shows that a larger reduction in the lattice thermal conductivity was measured in the MS sample, where a nearly 20% reduction is observed over the entire temperature range. This is likely due to the smaller grain size in the MS samples where a significant increase in the number of grain boundaries provides additional phonon scattering. The MS sample also shows a higher ZT value over the entire temperature range, with a peak enhancement of about 15% at around 625 K.

### V. Thermoelectric Devices

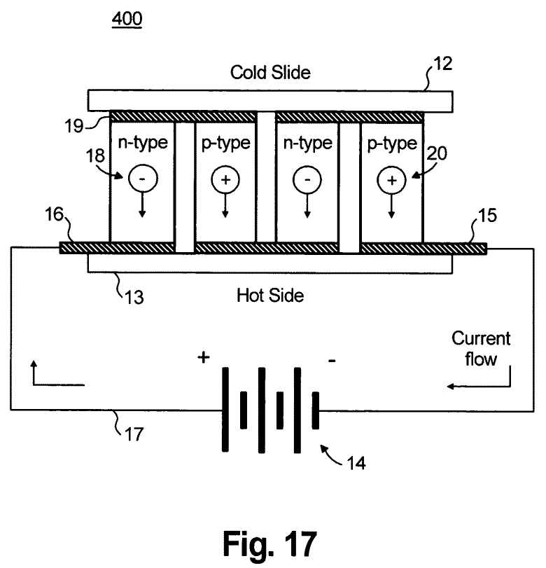

An exemplary embodiment of a thermoelectric device which incorporates a plurality of n- and p-type filled skutterudites fabricated using the non-equilibrium process described in Section IV above will now be described in detail with reference to FIG. 17. In this embodiment the thermoelectric device (400) is shown in a configuration where it may be used as a solid state refrigerant. It is to be understood, however, that a thermoelectric device (400) may be configured to perform other functions such as heating, electric power generation, or temperature measurement and it is not necessary that the thermoelectric material used has the skutterudite crystal structure. The thermoelectric device (400) in FIG. 17 includes a cold plate (12) and a hot plate (13), each of which is typically constructed from an electrically insulating slab or substrate such as a ceramic material. The cold (12) and hot (13) plates are typically equipped with a cold sink and heat sink, respectively, to aid in the absorption and subsequent dissipation of heat transferred from the cold side to the hot side of the thermoelectric device. Sandwiched between the cold (12) and hot (13) plates are a plurality of n- (18) and p-type (20) thermoelectric elements which, in this embodiment, are filled skutterudites fabricated using the non-equilibrium synthesis process described in Section IV.

The thermoelectric elements are arranged in a periodic array such that each n-type element (18) is electrically connected to a p-type element (20) and each p-type element (20) is electrically connected to an n-type element (18) to form a series circuit as shown in FIG. 17. Electrical contact between each element is typically accomplished by means of a plurality of electrical connectors (19) which are formed on the interior surfaces of the cold (12) and hot (13) plates. The series of n-type (18) and p-type (20) thermoelectric elements is connected at each end to electrical connectors (15) and (16) which are, in turn, connected through an electrical circuit (17) to the terminals of a power source (14) such, for example, as a battery or electrical outlet. The configuration shown in FIG. 17 has the positive (+) terminal of the power source (14) connected to n-type element (18) through connector (16) whereas the negative (−) terminal is connected to p-type element (20) through connector (15).

When the power supply (14) is activated, a DC current flows through circuit (17) into n-type element (18), passes through the thermoelectric elements connected in series, and then flows out through p-type element (20) as indicated by the arrows in FIG. 17. The direction of current flow causes holes in the p-type elements to flow with the current and electrons in the n-type elements to flow against the current. This produces a net flux of the primary charge carriers in each element from the cold plate (12) to the hot plate (13). When current flows in this manner, heat energy is absorbed on the cold plate (12), transmitted through thermoelectric elements (18) and (20), and emitted as waste heat energy through hot plate (13). In this configuration the thermoelectric device (400) functions as a solid state refrigerant. It is to be understood, however, that the thermoelectric device (400) may also be configured to operate as a heater. This may be accomplished, for example, by reversing the direction of the current flow. The energy conversion efficiency of the thermoelectric device (400) is improved by incorporating filled skutterudites formed using the non-equilibrium synthesis routes disclosed in this specification as the thermoelectric elements (18) and (20).

It will be appreciated by persons skilled in the art that the present invention is not limited to what has been particularly shown and described in this specification. Rather, the scope of the present invention is defined by the claims which follow. It should further be understood that the above description is only representative of illustrative examples of embodiments. For the reader's convenience, the above description has focused on a representative sample of possible embodiments, a sample that teaches the principles of the present invention. Other embodiments may result from a different combination of portions of different embodiments.

The description has not attempted to exhaustively enumerate all possible variations. That alternate embodiments may not have been presented for a specific portion of the invention, and may result from a different combination of described portions, or that other undescribed alternate embodiments may be available for a portion, is not to be considered a disclaimer of those alternate embodiments. It will be appreciated that many of those undescribed embodiments are within the literal scope of the following claims, and others are equivalent. Furthermore, all references, publications, U.S. patents, and U.S. patent application Publications cited throughout this specification are incorporated by reference as if fully set forth in this specification.

1. A method of synthesizing a thermoelectric material, the method comprising:
heating constituents of the thermoelectric material to form a molten liquid;
cooling the molten liquid at a rate greater than or equal to 10⁵ K/s to form solid particles; and
sintering the solid particles at a predetermined temperature and pressure for a predetermined time period.

2. The method of claim 1, wherein the constituents of the thermoelectric material include Re, Fe, Co, and Sb.

3. The method of claim 1, wherein the constituents of the thermoelectric material include Bi, Te, Se, and Sb.

4. The method of claim 1, wherein the constituents of the thermoelectric material include Ce, Fe, and Sb.

5. The method of claim 4, wherein the thermoelectric material has the nominal chemical formula CeFe₄Sb₁₂.

6. The method of claim 1, wherein the constituents of the thermoelectric material include Ce, Fe, Co, and Sb.

7. The method of claim 6, wherein the thermoelectric material has the nominal chemical formula Ce_{0.9}Fe₃CoSb₁₂.

8. The method of claim 1, wherein the molten liquid is cooled at a rate greater than or equal to 10⁶ K/s to form solid particles.

9. The method of claim 1, wherein the predetermined temperature is between 350° C. to 750° C.

10. The method of claim 9, wherein the predetermined temperature is between 500° C. to 700° C.

11. The method of claim 1, wherein the predetermined pressure is between 1 MPa and 200 MPa.

12. The method of claim 1, wherein the molten liquid is cooled by melt-spinning.

13. The method of claim 12, wherein the time from when a stream of the molten liquid first begins to cool to the end of the flow is 0.1 to 8 seconds for a sample size of 1 to 100 grams.

14. The method of claim 1, wherein the molten liquid is cooled by splash quenching or thermal spraying.

15. The method of claim 1, wherein the solid particles are packed into a mold having a predetermined shape before sintering.

16. The method of claim 1, wherein the solid particles are sintered by hot pressing.

17. The method of claim 1, wherein the solid particles are sintered by spark plasma sintering.

18. The method of claim 17, wherein spark plasma sintering is performed at a temperature of 585° C. and applied force of 6.3 kN over an area of about 64 mm² for 2 minutes.

19. The method of claim 17, wherein spark plasma sintering is performed at a temperature of 600° C. and pressure of 50 MPa for 2 minutes.

20. The method of claim 17, wherein spark plasma sintering is performed at a temperature of 620° C. and pressure of 50 MPa for 2 minutes.

21. A method of synthesizing a thermoelectric material, the method comprising:
forming a mixture comprising a predetermined ratio of each constituent of the thermoelectric material;
heating the mixture to form a molten liquid;
cooling the molten liquid at a rate of greater than or equal to 10⁵ K/s to form solid particles;
packing the solid particles into a mold; and
sintering the mold at a predetermined temperature and pressure for a predetermined time period.

22. The method of claim 21, wherein the molten liquid is cooled at a rate greater than or equal to 10⁶ K/s to form solid particles.

23. A thermoelectric material synthesized from a method comprising:
heating the constituents of the thermoelectric material to form a molten liquid;
cooling the molten liquid at a rate of greater than or equal to 10⁵ K/s to form solid particles; and
sintering the solid particles at a predetermined temperature and pressure for a predetermined time period.

24. The thermoelectric material of claim 23, wherein the grain size is between 2 nm and 1 μm.

25. The thermoelectric material of claim 23, wherein the constituents of the thermoelectric material include Re, Fe, Co, and Sb.

26. The thermoelectric material of claim 23, wherein the constituents of the thermoelectric material include Bi, Te, Se, and Sb.

27. The thermoelectric material of claim 23, wherein the constituents of the thermoelectric material include Ce, Fe, and Sb.

28. The thermoelectric material of claim 27, wherein the thermoelectric material has the nominal chemical formula CeFe₄Sb₁₂.

29. The thermoelectric material of claim 23, wherein the constituents of the thermoelectric material include Ce, Fe, Co, and Sb.

30. The thermoelectric material of claim 29, wherein the thermoelectric material has the nominal chemical formula Ce_{0.9}Fe₃CoSb₁₂.

31. The thermoelectric material of claim 23, wherein the molten liquid is cooled at a rate greater than or equal to 10⁶ K/s to form solid particles.

32. The thermoelectric material of claim 23, wherein the molten liquid is cooled by melt-spinning.

33. The thermoelectric material of claim 32, wherein the time from when a stream of the molten liquid first begins to cool to the end of the flow is 0.1 to 8 seconds for a sample size of 1 to 100 grams.

34. The thermoelectric material of claim 23, wherein the molten liquid is cooled by splash quenching or thermal spraying.

35. The thermoelectric material of claim 23, wherein the solid particles are packed into a mold having a predetermined shape before sintering.

36. The thermoelectric material of claim 23, wherein the predetermined temperature is between 350° C. to 750° C.

37. The thermoelectric material of claim 36, wherein the predetermined temperature is between 500° C. to 700° C.

38. The thermoelectric material of claim 23, wherein the predetermined pressure is between 1 MPa and 200 MPa.

39. The thermoelectric material of claim 23, wherein the solid particles are sintered by hot pressing.

40. The thermoelectric material of claim 23, wherein the solid particles are sintered by spark plasma sintering.

41. The thermoelectric material of claim 40, wherein spark plasma sintering is performed at a temperature of 585° C. and applied force of 6.3 kN over an area of about 64 mm² for 2 minutes.

42. The thermoelectric material of claim 40, wherein spark plasma sintering is performed at a temperature of 600° C. and pressure of 50 MPa for 2 minutes.

43. The thermoelectric material of claim 40, wherein spark plasma sintering is performed at a temperature of 620° C. and pressure of 50 MPa for 2 minutes.

44. A thermoelectric device comprising a current source, a hot electrode, a cold electrode, and a plurality of thermoelectric materials situated between the hot and cold electrodes, said thermoelectric materials being synthesized using a method comprising:
heating constituents of the thermoelectric material to form a molten liquid;
cooling the molten liquid at a rate greater than or equal to 10⁵ K/s to form solid particles;
packing the particles into a mold; and
sintering the solid particles at a predetermined temperature and pressure for a predetermined time period.

45. The thermoelectric material of claim 44, wherein the molten liquid is cooled at a rate greater than or equal to 10⁶ K/s to form solid particles.

46. The thermoelectric device of claim 44, wherein the thermoelectric device is configured to function as either a cooling or heating source depending on the polarity of the current source.
